(19) United States
(12) Patent Application Publication
(10) Pub. No.: US 2011/0248698 A1
(43) Pub. Date: Oct. 13, 2011

(54) BIOSENSOR AND DETECTION METHOD OF TARGET SUBSTANCE

(76) Inventors: Hiroaki Kikuchi, Tokyo (JP); Tomoaki Yamabayashi, Tokyo (JP); Osamu Takahashi, Tokyo (JP)

(21) Appl. No.: 13/081,003

(22) Filed: Apr. 6, 2011

(30) Foreign Application Priority Data
Apr. 8, 2010 (JP) 2010-089479

(51) Int. Cl. G01R 19/00; H01L 29/66

(52) U.S. Cl. 324/76.11; 257/253; 257/E29.166

(57) ABSTRACT

A biosensor includes at least two field effect transistor devices, each including a silicon substrate, a silicon oxide film formed on a surface of the silicon substrate, a source electrode disposed on the silicon oxide film, a drain electrode disposed on the silicon oxide film, a channel for connecting the source electrode and the drain electrode, and a gate electrode capable of controlling the channel, wherein one of the at least two field effect transistor devices is provided with a reaction field on which a target recognition molecule is to be immobilized, and the other one of the at least two field effect transistor devices is provided with a reaction field on which a target recognition molecule is not to be immobilized.

### CROSS REFERENCE TO RELATED APPLICATION

This application is entitled and claims the benefit of Japanese Patent Application No. 2010-089479, filed on Apr. 8, 2010, the disclosure of which including the specification, drawings and abstract is incorporated herein by reference in its entirety.

### TECHNICAL FIELD

This disclosure relates to a biosensor having a field effect transistor device, and a detection method of a target substance using the same.

### BACKGROUND ART

Biosensors that utilize a field effect transistor have heretofore been proposed (see Patent References 1 to 3). Generally, in such a field-effect transistor biosensor, source/drain electrodes and a channel are formed on an insulating film formed on a semiconductor substrate, and in many cases, a reaction field is disposed on the channel or insulating film on the semiconductor substrate. Target recognition molecules are often immobilized on the reaction field.

In such a biosensor, target recognition molecules immobilized on the reaction field are allowed to recognize a target substance. The biosensor then measures a source-drain current upon target recognition to determine the presence or concentration of the target substance provided to the reaction field.
Patent Reference 1: Japanese Patent Application Laid-Open No. 2004-85392
Patent Reference 2: Japanese Patent Application Laid-Open No. 2006-201178
Patent Reference 3: Japanese Patent Application Laid-Open No. 2007-139762

### SUMMARY OF INVENTION

### Technical Problem

As mentioned above, the field-effect transistor biosensor determines the presence or concentration of a target substance based on the source-drain current of a field effect transistor. A source-drain current of a field effect transistor greatly varies depending on the measurement environment. Examples of measurement conditions that cause variations in a source-drain current include ambient temperature and lightness (amount of light). Variations in source-drain current associated with changes in the measurement environment impede precise detection.

It is therefore an object of the present invention to provide a biosensor capable of precise target detection regardless of measurement conditions such as ambient temperature and lightness, even though the device has a field effect transistor.

### Solution to Problem

The present invention is directed to a biosensor having at least two field effect transistor devices, one as a device for detecting a target substance and the other as a device for correcting noise associated with changes in the measurement environment. Specifically, a first aspect of the present invention relates to biosensors given below.

[1] A biosensor including:

at least two field effect transistor devices, each including a silicon substrate, a silicon oxide film formed on a surface of the silicon substrate, a source electrode disposed on the silicon oxide film, a drain electrode disposed on the silicon oxide film, a channel for connecting the source electrode and the drain electrode, and a gate electrode capable of controlling the channel,

wherein one of the at least two field effect transistor devices is provided with a reaction field on which a target recognition molecule is to be immobilized, and the other one of the at least two field effect transistor devices is provided with a reaction field on which a target recognition molecule is not to be immobilized.

[2] The biosensor according to [1], wherein the silicon substrates of the at least two field effect transistor devices are set apart from each other.

[3] The biosensor according to [1], wherein the at least two field effect transistor devices share the same silicon substrate, and the gate electrodes of the at least two field effect transistor devices are set apart from each other.

[4] The biosensor according to any one of [1] to [3], wherein a voltage applied to the gate electrode is +0.5 V to −0.5 V.

A second aspect of the present invention relates to a detection method given below.

[5] A detection method of a target substance with the biosensor according to claim 1, the method including:

providing a sample to the respective reaction fields of the at least two field effect transistor devices;

measuring a source-drain current of each of the at least two field effect transistor devices; and

correcting the source-drain current of one of the at least two field effect transistor devices with the source-current of the other one of the at least two field effect transistor devices.

[6] The detection method according to [5], wherein a voltage applied to the gate electrode upon measurement of the source-drain current of each of the at least two field effect transistor devices is +0.5V to −0.5V.

### Advantageous Effects of Invention

A field-effect transistor biosensor of the present invention is capable of high-precise target detection regardless of measurement conditions such as ambient temperature and lightness; therefore, the present invention contributes to the practical use of a field-effect transistor biosensor.

Moreover, the biosensor of the present invention eliminates the need to provide a detection apparatus with a noise cancelling mechanism and to store noise cancelling data in the detection apparatus, making it possible to simplify the detection apparatus.

### BRIEF DESCRIPTION OF DRAWINGS

FIG. 1 is a perspective view of a biosensor having a single field effect transistor device;

FIG. 2 is a graph showing changes in source-drain current of a field effect transistor device in response to ambient temperature changes;

FIG. 3A is a perspective view of a biosensor of a first example, which has two field effect transistor devices;

FIG. 3B is a sectional view of the biosensor illustrated in FIG. 3A;

FIG. 4A is a perspective view of a biosensor of a second example, which has two field effect transistor devices;

FIG. 4B is a sectional view of the biosensor illustrated in FIG. 4A;

FIG. 5 is a graph showing the generation of noise in source-drain currents respectively of field-effect transistor devices A and B in a biosensor of the present invention;

FIG. 6A is a graph showing a source-drain current of field effect transistor device A;

FIG. 6B is a graph showing a source-drain current of field effect transistor device B; and

FIG. 6C is a graph showing a result obtained by subtracting the source-drain current of field effect transistor device B of FIG. 6B from the source-drain current of field effect transistor device A of FIG. 6A.

### DESCRIPTION OF EMBODIMENTS

A biosensor of the present invention has field effect transistor devices. The field effect transistor device includes a semiconductor substrate; an insulating film formed on a surface of the semiconductor substrate; a source electrode disposed on the insulating film; a drain electrode disposed on the insulating film; a channel for connecting the source and drain electrodes; and a gate electrode capable of controlling the channel. The semiconductor substrate and insulating film are usually, but not necessarily, a silicon substrate and a silicon oxide film, respectively.

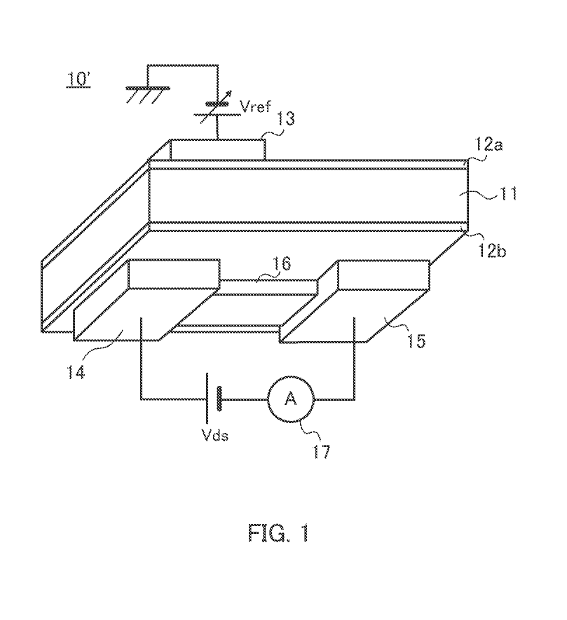

FIG. 1 illustrates an example of a biosensor having a single field effect transistor device. As illustrated in FIG. 1, in conventional biosensor 10′, drain electrode 14, source electrode 15 and channel 16 are disposed on silicon oxide film 12b formed on the surface of silicon substrate 11. Further, gate electrode 13 is disposed on silicon substrate 11 so as to act on channel 16. In FIG. 1, gate electrode 13 is disposed on silicon oxide film 12a formed on the rear surface of silicon substrate 11.

Channel 16 is, for example, but not limited to, a polysilicon channel; for example, channel 16 may be a carbon nanotube channel. Channel 16 may be of NPN-type, PNP-type, NiN-type, or PiP type. When channel 16 is NPN type or PNP type, the band gap of the channel is large, and therefore, leakage current tend to be small compared to the NiN-type or PiP-type channel. Consequently, with an NPN-type or PNP-type channel, an electric circuit that can reduce current consumption in stand-by mode can be readily constructed. The NiN-type or PiP-type channel, on the other hand, may be manufactured in fewer steps than the NPN-type or PNP-type channel.

A biosensor having a single field effect transistor device, such as that illustrated in FIG. 1, sometimes fail to show uniform detection sensitivity. One of the causes of non-uniform detection sensitivity is that the device's characteristics undergo changes depending on the measurement environment, e.g., depending on ambient temperature or lightness.

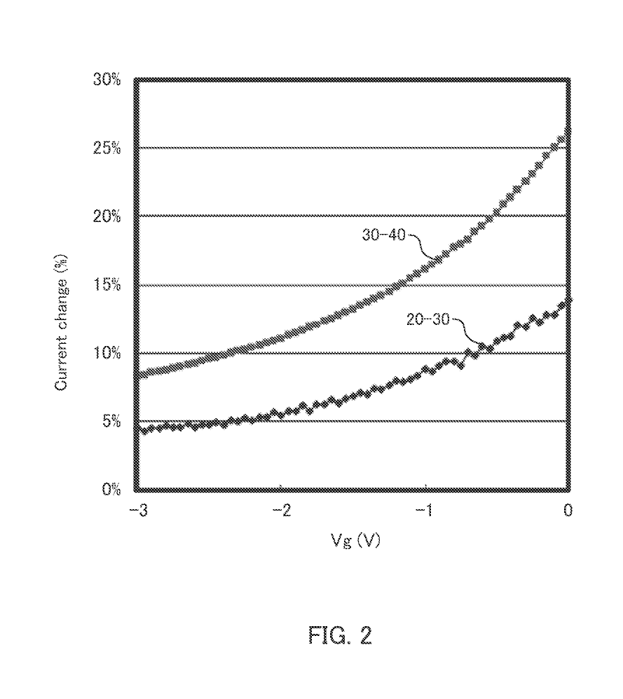

FIG. 2 is a graph showing degrees of change of a source-drain current of a field effect transistor in response to ambient temperature change. In FIG. 2, the horizontal axis represents gate voltage, and the longitudinal axis represents source-drain current change. The source-drain voltage was set to 6 V, and the gate voltage range was set to −3 V to 0 V. FIG. 2 shows changes in source-drain current for ambient temperature elevation from 20 to 30° C. (curve 20-30) and those for ambient temperature elevation from 30 to 40° C. (curve 30-40) over the entire gate voltage range.

As seen from FIG. 2, only 10° C. elevation in the ambient temperature results in a 5-25% source-drain current increase. In particular, changes in source-drain current in response to ambient temperature elevation increase with approaching 0 V gate voltage. Thus, with a biosensor having a single field effect transistor, precise target detection may fail due to changes in the source-drain current caused by slight changes in the measurement temperature.

In contrast to such a biosensor, the biosensor of the present invention uses at least two field effect transistor devices, one as a detection device and the other as a correction device.

Every field effect transistor device contained in the biosensor of the present invention includes a semiconductor substrate; an insulating film formed on a surface of the semiconductor substrate; a source electrode disposed on the insulating film; a drain electrode disposed on the insulating film; a channel for connecting the source and drain electrodes; and a gate electrode capable of controlling the channel. All of the field effect transistors preferably have the same constituent components (except for reaction field) and have the same structure. This makes uniform device characteristics, especially I-V characteristics, among the field effect transistors.

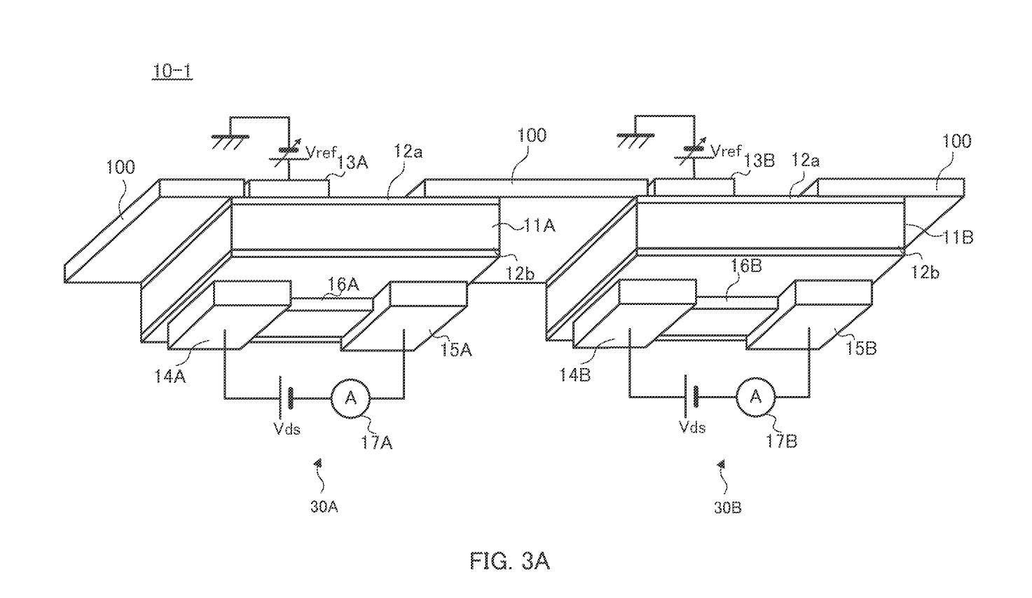

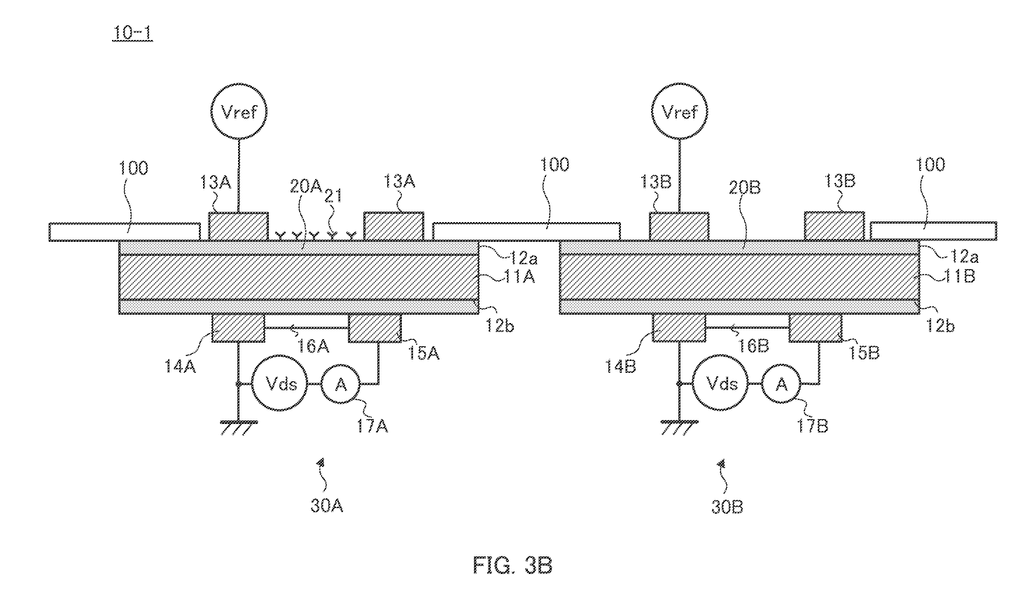

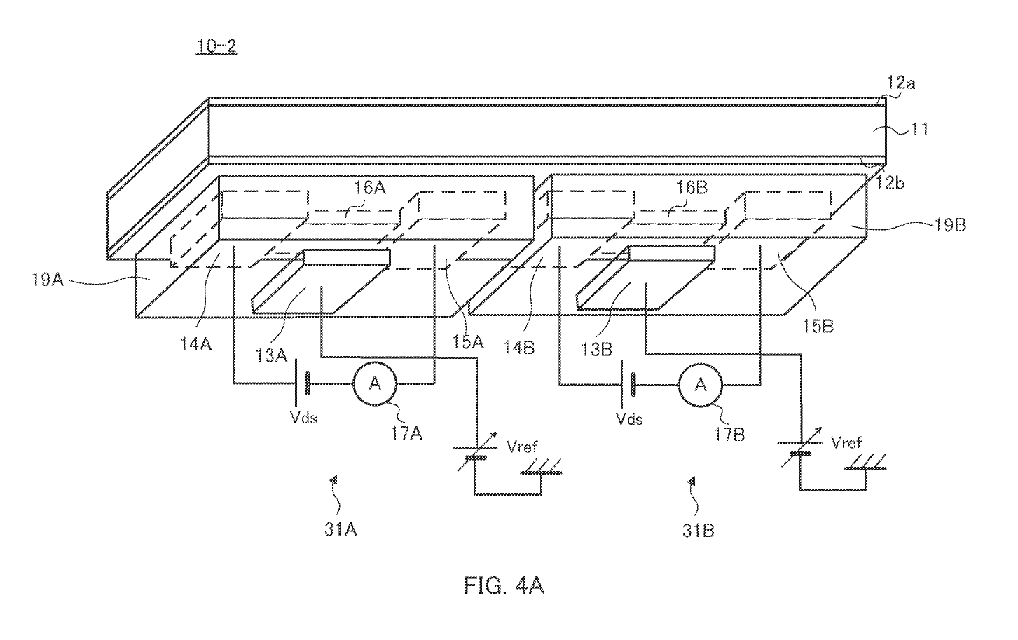

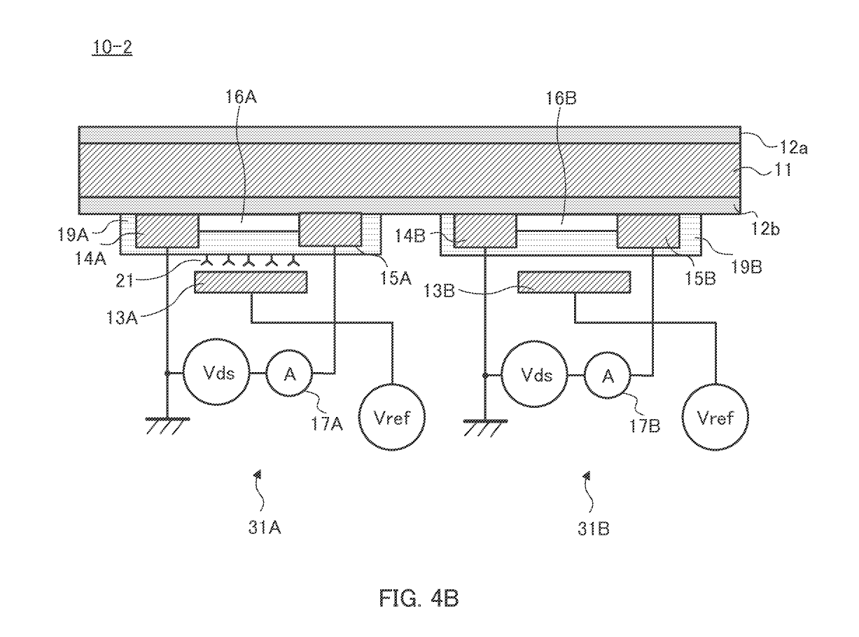

The field effect transistor devices may have own separate silicon substrates (see FIG. 3A) or may share a single common silicon substrate (see FIG. 4A). In the latter case, the field effect transistors have own separate gate electrodes (see FIG. 4A). In either case, the field effect transistors are so configured as to be controlled independently.

The field effect transistor devices contained in the biosensor of the present invention each have a reaction field. As used herein, the term “reaction field” means an area in which a sample (typically solution) which may contain a target substance is to be provided. The position of the reaction field is not particularly limited; it may be disposed on the surface of the semiconductor substrate (see FIG. 3B), or may be disposed on the gate insulating film that insulates between the channel and gate electrode (see FIG. 4B). For increased detection sensitivity, the reaction field is preferably disposed in the vicinity of the gate electrode.

Field effect transistor device A, one of the field effect transistor devices contained in the biosensor of the present invention, includes a reaction field on which target recognition molecules are to be immobilized. Field effect transistor device A is a device for detecting a target substance. Examples of target recognition molecules include proteins such as antibodies, enzymes and lectin, nucleic acid, oligosaccharides or polysaccharides, and substances having the structure of the foregoing. Immobilizing target recognition molecules on the reaction field allows for specific detection of specific types of proteins or chemicals.

On the other hand, field effect transistor device B, the other one of the field effect transistor devices contained in the biosensor of the present invention, includes a reaction field on which no target recognition molecule are immobilized. Field effect transistor device B is a device for correcting detection data of field effect transistor device A.

FIG. 3A illustrates a first example of a biosensor of the present invention. Biosensor 10-1 illustrated in FIG. 3A includes mounting substrate 100 and two field effect transistor devices 30A and 30B mounted thereon. Field effect transistor devices 30A and 30B each have the same structure as the field effect transistor device illustrated in FIG. 1.

FIG. 3B is a sectional view of biosensor 10-1 illustrated in FIG. 3A. As illustrated in FIG. 3B, both of field effect transistor device 30A and device 30B are mounted on mounting substrate 100. Field effect transistor devices 30A and 30B each have reaction field 20 (20A or 20B) on silicon oxide film 12a formed on the surface of silicon substrate 11 (11A or 11B). Gate electrode 13A is disposed around reaction field 20A, and gate electrode 13B is disposed around reaction field 20B. Target recognition molecules 21 are immobilized on reaction field 20A, whereas no target recognition molecules are immobilized on reaction field 20B.

FIG. 4A illustrates a second example of a biosensor of the present invention. Biosensor 10-2 illustrated in FIG. 4A includes silicon substrate 11 on which silicon oxide film 12b is formed, and two field effect transistor devices 31 (31A and 31B) disposed on silicon oxide film 12b. Each field effect transistor device includes drain electrode 14 (14A or 14B), source electrode 15 (15A or 15B), channel 16 (16A or 16B), and gate insulating film 19 (19A or 19B). Field effect transistor devices 31A and 31B include so-called top gate-type gate electrodes 13 (13A and 13B), respectively, disposed on gate insulating film 19.

FIG. 4B is a sectional view of biosensor 10-2 illustrated in FIG. 4A. As illustrated in FIG. 4B, in field effect transistor device 31A, a region of gate insulating film 19A near channel 16A forms a reaction field on which target recognition molecules 21 are immobilized. On the other hand, in field effect transistor device 31B, a region of gate insulating film 19B near channel 16B forms a reaction field on which target recognition molecules 21 are not immobilized.

Target Detection Flow Using Biosensor

Detection of a target substance using a biosensor of the present invention starts by providing a sample, which may contain a target substance, to the reaction field of field effect transistor device A (reaction field on which target recognition molecules are immobilized).

The same sample is also provided to the reaction field of field effect transistor device B (reaction field on which target recognition molecules are not immobilized). The target recognition molecules immobilized on the reaction field of field effect transistor device A react with a target substance in the sample. By contrast, no reaction takes place in the reaction field of field effect transistor device B because of the absence of target recognition molecules. Where necessary, the sample's solvent and other components are then removed from the respective reaction fields.

The same level of a given gate voltage is applied to the gate electrodes of field effect transistor devices A and B. For example, a voltage applied to the gate electrodes of field effect transistor devices A and B is +0.5 V to −0.5 V. At this time, source-drain currents of field effect transistor devices A and B are respectively measured. Due to slight changes in the measurement environment, such as changes in ambient temperature or lightness, noise may occur in both of the source-drain currents of field effect transistor devices A and B. The source-drain currents show similar noise patterns, because field effect transistors device A and B have the same device structure.

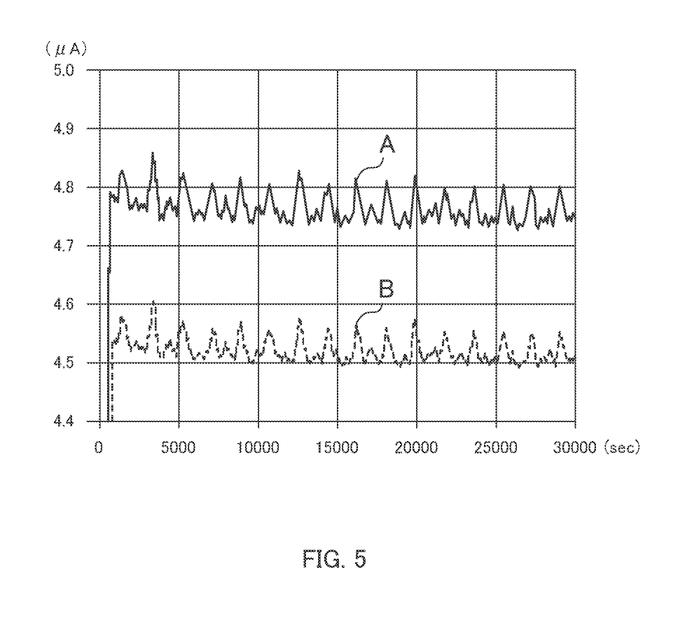

FIG. 5 is a graph showing noise generated in the source-drain currents of the two field effect transistors (field effect transistor devices A and B). A PIP-type polysilicon channel was employed in each field effect transistor, with the channel width set to 200 μm and channel length set to 4 μm. The thickness of the gate oxidized film was set to 270 Å. Measurements were made while changing the measurement temperature within room temperature ±3° C.

In FIG. 5, the longitudinal axis represents a source-drain current (μA) of the field effect transistor device, and the horizontal axis represents time (second). In FIG. 5, the solid line curve represents a source-drain current of field effect transistor device A, and the dashed line curve represents a source-drain current of field effect transistor device B. For both of the field effect transistor devices A and B, the gate voltage was set to 0 V and the source-drain voltage was set to 6 V. As seen from FIG. 5, large noise was generated in the source-drain currents of field effect transistor devices A and B. It can be seen, however, that the noises in field effect transistor devices A and B are synchronized with each other. This suggests that source-drain current noise occurs in accordance with changes in the ambient environment.

Thus, it can be seen that a noise-cancelled source-drain current can be obtained for field effect transistor device A by correcting the source-drain current of field effect transistor device A with the source-drain current of field effect transistor device B.

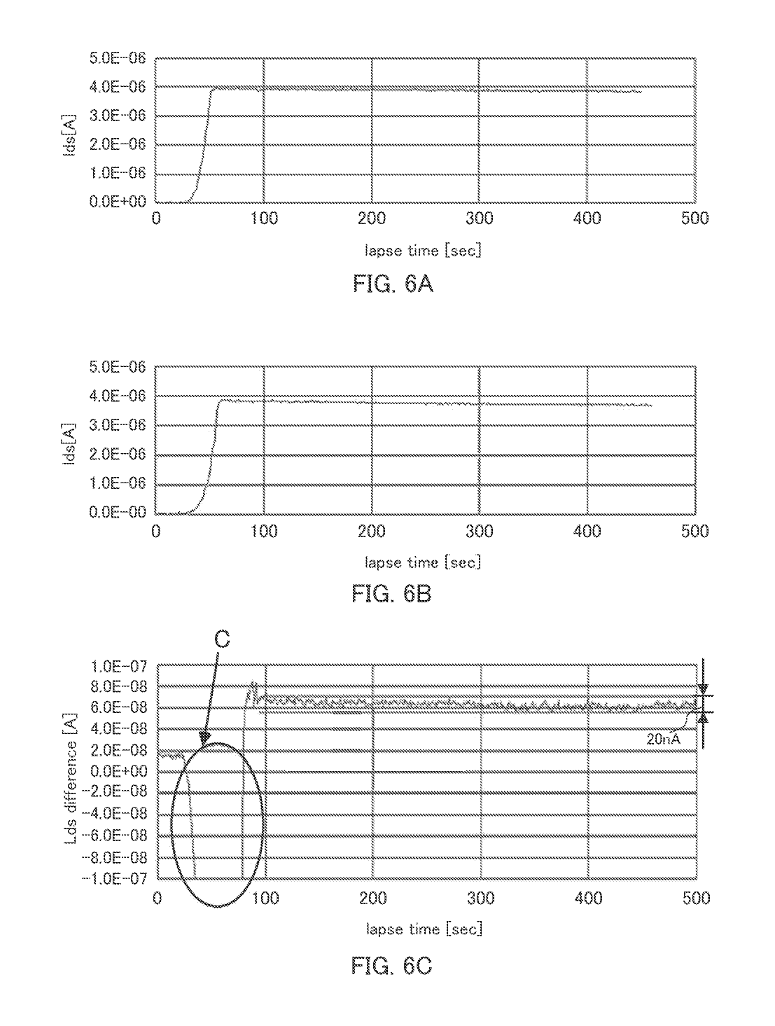

With reference to FIGS. 6A to 6C, the following describes how the biosensor of the present invention produces a noise-cancelled source-drain current. In FIGS. 6A to 6C, the longitudinal axis represents a source-drain current (A) of field effect transistor device, and the horizontal axis represents time (second).

FIG. 6A shows a source-drain current of field effect transistor device A (IdsA), and FIG. 6B illustrates a source-drain current of field effect transistor device B (IdsB). Measurement conditions are as follows: temperature=room temperature; gate voltage=0 V; and source-drain voltage=6 V. In both of FIGS. 6A and 6B, noise width was about 100 nA to about 150 nA. This noise potentially impedes precise target detection. FIG. 6C shows a result obtained by subtracting the source-drain current of field effect transistor device B (FIG. 6B) from the source-drain current of field effect transistor device A (FIG. 6A), (IdsA-IdsB). As shown in FIG. 6C, the difference is within 20 nA. Thus, it can be seen that noise can be cancelled by correcting the source-drain current of field effect transistor device A with the source-drain current of field effect transistor device B. Note in FIG. 6C that a fall indicated by arrow C is derived from the difference in start-up response time between field effect transistor devices A and B.

Typical biosensor apparatus require a mechanism for suppressing noise in the measured values in the biosensor or a mechanism for cancelling the generated noise. The noise suppressing mechanism is, for example, a mechanism for keeping the measurement temperature constant or a light-shielding mechanism. The noise cancelling mechanism is, for example, a mechanism for correcting the measured values in the biosensor using predicted noise patterns stored in the mechanism in advance.

The biosensor of the present invention, on the other hand, requires neither a noise suppressing mechanism nor a noise cancelling mechanism, since the biosensor itself has a noise cancelling function. Thus, according to the present invention, a simple and small biosensor apparatus may be provided.

### INDUSTRIAL APPLICABILITY

Because possible noise that occurs due to the measurement environment can be cancelled, the biosensor of the present invention is capable of highly sensitive and precise target detection even though the device has a field effect transistor.

What is claimed is:

1. A biosensor comprising:
at least two field effect transistor devices, each including a silicon substrate, a silicon oxide film formed on a surface of the silicon substrate, a source electrode disposed on the silicon oxide film, a drain electrode disposed on the silicon oxide film, a channel for connecting the source electrode and the drain electrode, and a gate electrode capable of controlling the channel,
wherein one of the at least two field effect transistor devices is provided with a reaction field on which a target recognition molecule is to be immobilized, and the other of the at least two field effect transistor devices is provided with a reaction field on which a target recognition molecule is not to be immobilized.

2. The biosensor according to claim 1, wherein the silicon substrates of the at least two field effect transistor devices are disposed apart from each other.

3. The biosensor according to claim 1, wherein the at least two field effect transistor devices share a common silicon substrate, and the gate electrodes of the at least two field effect transistor devices are disposed apart from each other.

4. The biosensor according to claim 1, wherein the gate electrodes are arranged to receive a voltage between +0.5 V and −0.5 V.

5. A detection method of a target substance with the biosensor according to claim 1, comprising the steps of:
providing a sample to the reaction fields of the at least two field effect transistor devices;
measuring a source-drain current of each of the at least two field effect transistor devices; and
correcting the source-drain current of one of the at least two field effect transistor devices with the source-current of the other one of the at least two field effect transistor devices.

6. The detection method according to claim 5, wherein, in the step of measuring the source-drain current of each of the at least two field effect transistor devices, a voltage between +0.5 V and −0.5 V is applied to the gate electrodes.
